(19) United States
(12) Patent Application Publication
(10) Pub. No.: US 2011/0175099 A1
(43) Pub. Date: Jul. 21, 2011

(54) LITHOGRAPHIC METHOD OF MAKING UNIFORM CRYSTALLINE SI FILMS

(75) Inventor: James S. Im, New York, NY (US)

(73) Assignee: The Trustees of Columbia University in the City of New York, New York, NY (US)

(21) Appl. No.: 12/919,688

(22) PCT Filed: Mar. 2, 2009
(86) PCT No.: PCT/US09/35732

§ 371 Date: Jan. 25, 2011

Related U.S. Application Data
(60) Provisional application No. 61/032,744, filed on Feb. 29, 2008.

(51) Int. Cl. H01L 29/04; H01L 21/26

(52) U.S. Cl. 257/64; 438/758; 257/E29.004; 257/E21.328

(57) ABSTRACT

Methods and devices are described relating to an electronic device positioned at a known location in a crystalline film including a crystalline semiconductor comprising a region of location controlled crystalline grains; a device located in the crystalline semiconductor film at a location that is defined relative to the location of the location controlled crystalline grains. The method includes irradiating at least a portion of a semiconductor film using two or more overlapping irradiation steps, wherein each irradiation step at least partially melts and laterally crystallizes a lithographically defined region the film to obtain a region of laterally grown crystalline grains having at least one long grain boundary that is perpendicular to the lateral growth length; identifying the location of at least one long grain boundary; and manufacturing an electronic device in the semiconductor film at a location that is defined relative to the location of the long grain boundary.

### CROSS-REFERENCE RELATED APPLICATIONS

This application claims the benefit of priority under 35 U.S.C. 119(e) to co-pending U.S. Application No. 61/032,744, filed Feb. 29, 2008, and entitled “LITHOGRAPHY BASED SEQUENTIAL LATERAL SOLIDIFICATION,” which is hereby incorporated in its entirety by reference.

### INCORPORATION BY REFERENCE

All patents, patent applications and publications cited herein are hereby incorporated by reference in their entirety in order to more fully describe the state of the art as known to those skilled therein as of the date of the invention described herein.

### BACKGROUND

In recent years, various techniques have been investigated for crystallizing or improving the crystallinity of an amorphous or polycrystalline semiconductor film. Such crystallized thin films can be used in the manufacturing of a variety of devices, such as image sensors and active-matrix liquid-crystal display (“AMLCD”) devices. In the latter, a regular array of thin-film transistors (“TFTs”) is fabricated on an appropriate transparent substrate, and each transistor serves as a pixel controller.

Semiconductor films, such as silicon films, have been processed for liquid crystal displays using various laser processes including excimer laser annealing (“ELA”) and sequential lateral solidification (“SLS”) processes. SLS is well suited to process thin films for use in AMLCD devices, as well as organic light emitting diode (“OLED”) and active-matrix OLED (AMOLED) devices. A feature of SLS is the control of lateral crystal growth using excimer laser irradiation. Lateral growth is initiated when irradiated regions are fully melted and solidification is initiated at the solidus-liquidus interface between masked and unmasked regions. The lateral growth length (LGL) is a function of the film properties and irradiation conditions. Conventional SLS techniques do not permit precise location of laterally grown crystalline regions, leading to variation in device properties prepared in SLS-processed films.

### SUMMARY

This application describes lithographic procedures to create uniform poly-Si films or larger-grain Si films. This application also describes lithographic procedures to create orientation-controlled single-crystal regions.

In one aspect, an apparatus includes a semiconductor film having at least one region of laterally grown crystalline grains and a device located in said region at a location that is defined relative to the location of at least one long grain boundary of the crystalline grains. The grains include at least one long grain boundary that is perpendicular to the direction of lateral growth, and have substantially uniform grain structure in which greater than about 50% of the grains have a length longer than the lateral growth length.

In on aspect, an apparatus includes a semiconductor film having at least one region of laterally grown crystalline grains and a device located in said region at a location that is defined relative to the location of at least one long grain boundary of the crystalline grains. The grains comprising at least one pair of substantially parallel long grain boundaries and a plurality of laterally grown grains spanning between adjacent long grain boundaries, and said grains having substantially uniform grain structure in which greater than about 50% of the grains have a length longer than the lateral growth length.

In one or more embodiments, the location of the long grain boundaries on the film are known with an accuracy of less than 10% of the lateral growth length, with an accuracy of less than 5% of the lateral growth length.

In one or more embodiments, the device is a transistor, comprising a channel source and drain, and for example, the transistor is a field effect transistor (FET) and is positioned within the region at a location where the channel of the FET does not contain a long grain boundary, or the FET is positioned within the region at a location where the source or the drain of the FET does not contain a long grain boundary, or the FET is positioned within a region at a location where the channel intersects a long grain boundary at a known location.

In one aspect, an apparatus includes a semiconductor film comprising a plurality of laterally grown crystalline islands and a device located in said region at a location that is defined relative to the location of at least one long grain boundary of the crystalline islands. The islands include at least one long grain boundary, the long grain boundary circumscribing one of the islands at a distance from the island center of greater than the lateral growth length, and more than 90% of the islands have the same crystallographic surface orientation.

In one or more embodiments, the crystallographic surface orientation is a {100} plane, and optionally, the crystalline grain orientation comprises about 90% of the island surface area having a {100} surface orientation within about 15° of the {100} pole.

In one or more embodiments, the crystallographic surface orientation is a {111} plane, and optionally, the crystalline grain orientation comprises about 90% of the island surface area having a {100} surface orientation within about 15° of the {111} pole.

In one or more embodiments, the location of the long grain boundaries on the film are known with an accuracy of less than 20% of the lateral growth length, or the location of the long grain boundaries on the film are known with an accuracy of less than 10% of the lateral growth length.

In one or more embodiments, the device is a FET, comprising a channel source and drain, and the FET is positioned within the region at a location where the channel of the FET does not contain a long grain boundary.

In one aspect, a method of making an apparatus includes first irradiating a first region of a semiconductor film under a first set of conditions that induce controlled superlateral growth from a first boundary in the film, wherein the first boundary is lithographically defined; second irradiating a second region of the film that only partially overlaps the first region under a second set of conditions that induce controlled superlateral growth from a second boundary in the film, wherein the second boundary is lithographically defined, wherein said first and second irradiating provide a film comprising laterally grown crystalline grains having a length longer than the lateral growth length and at least one long grain boundary, wherein the location of the long grain boundary is known to within 20% of a lateral growth length; and manufacturing an electronic device in the semiconductor film at a location that is defined relative to the location of the long grain boundary.

In one or more embodiments, the irradiation of the first region, the second region or both melts the semiconductor film through out its thickness.

In one or more embodiments, irradiation for at least one of the first and second irradiation is a flood irradiation.

In one or more embodiments, the lithographically defined boundary is provided by lithographically forming a cap layer over at least a portion of the film.

In one or more embodiments, the cap has a pattern that exposes the underlying semiconductor film to irradiation in lithographically defined locations.

In one or more embodiments, the lithographically defined boundary is provided by lower layer disposed below the film.

In one or more embodiments, the lower layer is a heat absorbing material and wherein, during irradiation using a wavelength that is absorbed by the semiconductor film, the temperature of the overlying semiconductor film at lithographically defined locations is less than the temperature of adjacent regions of the semiconductor film.

In one or more embodiments, the lower layer is a material that is a heat absorbing material and wherein, during irradiation using a wavelength that is transparent to the semiconductor film, the temperature of the overlying semiconductor film at lithographically defined locations is greater than the temperature of adjacent regions of the semiconductor film.

In one or more embodiments, the cap layer is comprised of a material that is opaque to the energy of irradiation.

In one or more embodiments, the cap layer is comprised of a material that is reflective to the energy of irradiation.

In one or more embodiments, the cap layer is a lithographically defined dot or array of dots.

In one or more embodiments, the irradiation includes irradiating a first region surrounding a first lithographically defined dot cap layer to melt the first region while the area under the first dot remains at least partially solid, wherein the melted region laterally crystallized from the interface between the solid and the liquid; removing the first dot cap layer; lithographically depositing a second cap layer, wherein the second dot cap layer overlaps a laterally crystallized portion of the first irradiation; and irradiating a second region surrounding the second lithographically deposited dot cap layer to melt the second region while the area under the second dot remains at least partially solid, wherein the melted region laterally crystallized from the interface between the solid and the liquid.

In one or more embodiments, the cap layer exposes elongated regions of underlying semiconductor film, wherein the exposed region defines a geometry having at least one dimension that is less than twice the characteristic lateral growth length of the semiconductor film.

In one or more embodiments, the location of the long grain boundaries on the film are known to an accuracy of less than 20% of the lateral growth length.

In one or more embodiments, the irradiation step includes irradiating at least a portion of the film to fully melt the exposed elongated regions of the underlying film, while the area under the first cap layer remains at least partially solid, wherein the melted region laterally crystallized from the interface the solid and the liquid; removing the first cap layer; lithographically depositing a second cap layer, wherein the second cap layer overlaps a laterally crystallized portion of the first irradiation; and irradiating at least a portion of the film to fully melt the exposed elongated regions of the underlying film, while the area under the second cap layer remains at least partially solid, wherein the melted region laterally crystallized from the interface between the solid and the liquid.

In one or more embodiments, the location of the long grain boundary is directed by the location of the lithographically placed boundaries and the lateral growth length of the grains.

In one or more embodiments, the location of the long grain boundaries on the film are known to an accuracy of less than 10% of the lateral growth length, or to an accuracy of less than 5% of the lateral growth length.

In one or more embodiments, the device comprises a FET.

In another aspect, a method of processing a film includes providing a semiconductor film having a heat sink disposed below the film, said heat sink positioned using a lithographic method; irradiating the film at an energy density sufficient to only partially melt a film region located above the heat sink and fully melt the film adjacent to the partially melted region, wherein the melted region laterally crystallized from the interface of the partially melted region and the liquid; positioning a cap layer over film in a pattern that exposes a portion of the laterally crystallized film; and irradiating with film at an energy density sufficient to fully melt the exposed film throughout its thickness, while the area under the cap layer remains at least partially solid, wherein the melted region laterally crystallizes from the interface of the solid and the liquid.

In another aspect, a method of processing a film includes providing a semiconductor film having a first cap layer disposed above the film having a pattern that exposes a portion of the film, said cap layer positioned using a lithographic method; irradiating the film at a first energy density sufficient to fully melt the exposed portion of the film throughout its thickness, while the area under the first cap layer remains at least partially solid wherein the melted region laterally crystallized from the interface of the partially melted region and the liquid; positioning a second cap layer over film in a pattern that exposes a portion of the laterally crystallized film; and irradiating with film at a second energy density sufficient to fully melt the exposed portion of the film throughout its thickness, while the area under the second cap layer remains at least partially solid wherein the melted region laterally crystallized from the interface of the partially melted region and the liquid.

In another aspect, a method of making an apparatus includes irradiating at least a portion of a semiconductor film using two or more overlapping irradiation steps, wherein each irradiation step at least partially melts and laterally crystallizes a lithographically defined region of the film to obtain a region of laterally grown crystalline grains having at least one long grain boundary that is perpendicular to the lateral growth length; identifying the location of at least one long grain boundary; and manufacturing an electronic device in the semiconductor film at a location that is defined relative to the location of the long grain boundary.

As used herein, “long grain boundary” is the grain boundary formed by termination of lateral crystal growth front in a film region, whether by collision with another set of laterally growing crystals or nucleation due to supercooling. The long boundary is typically, but not always perpendicular to the direction of lateral grain growth. A noted exception to this is the lateral growth using “dot” cap layers, as discussed in greater detail below.

As used herein, “laterally grown crystals” or “lateral crystalline growth” refers to the lateral growth of crystals that is initiated when fully melted regions solidify at an interface between a fully melted region and a seed crystal containing region. The seed containing region can be solid or partially melted.

A “ location that is defined relative to the location of at least one long grain boundary” refers to a location on a film based on the location of a long grain boundary that is known.

“Lithographically controlled” refers to the control of the location of a feature, such as a long grain boundary, by using lithography or other precision deposition method to precisely locate cap layers or other elements that are used in the irradiation and lateral growth of crystalline grains. The actual location of the feature will also be a function of the film characteristics, composition, thickness, etc., as well as the irradiation conditions, temperature, wavelength, pulse time, energy density, etc.

“Lithographically defined” refers to a characteristic of a region of the film whose location and/or dimensions are defined by lithography, for example, by interaction of the film having a lithographically formed feature, such as a cap layer, lower layer or heat sink, and incident light energy.

The methods permit placement of location-controlled crystalline regions with precision equivalent to the device process, e.g., placement of TFTs. Lithographic techniques are developed that ensure overlapped lateral growth to create more uniform microstructures. The methods provide flexibility in doing so.

### BRIEF DESCRIPTION OF THE DRAWINGS

The various aspects of the technology are described with reference to the following drawings, which are presented for the purpose of illustration only and which are not intended to be limiting of the invention.

FIG. 1 is a schematic illustration of the use of positive or negative photoresist to provide a precisely located pattern on a surface.

FIG. 2 is a top view illustration of a portion of a film crystallized using Controlled Super Lateral Growth (C-SLG) method, showing a typical C-SLG grain microstructure according to the prior art.

FIGS. 3 (a)-(d) depict cross sectional view of consecutive steps in a lithographically controlled crystallization process which is suitable for creating precision devices, according to one or more embodiments according to one or more embodiments.

FIGS. 4A and 4B are schematic illustrations of location placement on a lithographically crystallized semiconductor film according to one or more embodiments.

FIGS. 5A-5B provide a schematic illustration of a lithographic process using a cap layer providing a rectangular or line beam exposed area for irradiation in two sequential irradiation steps according to one or more embodiments.

FIGS. 6A-6C provide a schematic illustration of a lithographic process using a cap layer providing a rectangular or line beam exposed area for irradiation in three sequential irradiation steps according to one or more embodiments.

FIG. 7A is a schematic illustration of a dot matrix lithographic pattern for use according to one or more embodiments; and 7B is a schematic illustration of an irradiation pattern for use with a dot matric lithographic pattern of 7A.

FIG. 8 provides a schematic illustration of a lithographic process using a cap layer in the form of an opaque dot of irradiation in sequential irradiation steps according to one or more embodiments.

FIG. 9A-9B is a schematic illustration of the use of a lithographically located heat sink for providing a precisely located crystalline region in a semiconductor film according to one or more embodiments.

FIGS. 10A-10B is a schematic illustration of the use of a lithographically located heat sink for providing a precisely located crystalline region in a semiconductor film according to one or more embodiments.

FIG. 11 is a schematic illustration of a flash lamp irradiation system.

### DETAILED DESCRIPTION OF THE INVENTION

In order to create films that are suitable for precision devices, methods and systems are provided that crystallize the film and create a microstructure with the same precision as the precision used to create and position the precision device thereon. The precision device is often created using precise processes, for example, lithographic methods. The precision crystallization method controls the location and the size of defects, e.g, grains and grain boundaries, at the same scale and with the same precision as the size and position of the precision device. The location and dimension of such features can be known to the micrometer, submicrometer and even nanometer scale, which is referred to herein as “precise location.”

In some embodiments, the precision crystallization uses lithographic methods. Lithography patterning methods, and in particular photolithography, are capable of structuring material on a fine scale. The micro- and nanofabrication techniques used in the semiconductor industry provide very fine features of accurate dimensions that are precisely placed on a wafer. The positioning accuracy and dimensions of the features are known to within 10′s or 50′s of nanometers. The position accuracy of long grain boundaries (those that are perpendicular to the direction of lateral crystal growth) can range from less than about 20% to less than about 10% to about 5% of the lateral growth length of the crystal grains, depending on the type of crystallization method employed. Typical lateral growth lengths range from about 1 μm to about 4 μm. Thus, the location of the long grain boundary can be accurately placed within an error margin of as little as about 100 nm to about 800 nm. Most typically, the location of the long grain boundary can be accurately placed within an error margin of about 50 nm to about 300 nm.

In particular, the photolithographic process is used to selectively remove parts of a photoresist to generate a masked surface in which the pattern and location of the pattern features are precisely known. A mask set, a series of electronic data that define geometry for the photolithography steps of semiconductor fabrication, are used to define a mask pattern for use in crystallization of a silicon film. The masked surface can be irradiated to provide crystallized regions on a film whose pattern and location of the pattern features also are precisely known.

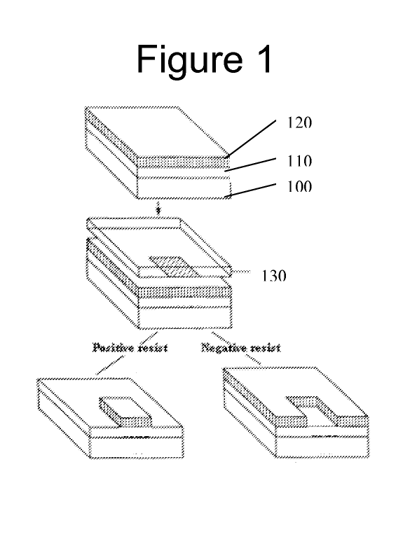

An exemplary photolithography method exemplifying this process is illustrated in FIG. 1. To prepare a silicon thin film for crystallization, an amorphous or low crystallinity silicon thin film 110 on a substrate 100 is coated with a layer of photoresist 120. A mask 130 that contains the pattern to be transferred onto the photoresist is positioned above the photoresist layer. There are at least two types of common photoresist: positive and negative. For positive resists, the resist is exposed with UV light wherever the underlying material is to be removed. In these resists, exposure to the UV light changes the chemical structure of the resist so that it becomes more soluble in the developer. The exposed resist is then washed away by the developer solution, leaving windows of the bare underlying material. The mask, therefore, contains an exact copy of the pattern which is to remain on the wafer. Negative resists behave in just the opposite manner. Exposure to the UV light causes the negative resist to become polymerized, and more difficult to dissolve. Therefore, the negative resist remains on the surface wherever it is exposed, and the developer solution removes only the unexposed portions. Masks used for negative photoresists, therefore, contain the inverse (or photographic “negative”) of the pattern to be transferred. Typically the photoresist itself can be used as the cover layer, assuming that it has the necessary heat stability to maintain its integrity during irradiation. The photoresist can be baked to increase its strength and heat resistance. In other embodiments, the photoresist can serve as a pattern for transfer of the cover layer to the silicon surface. For example, when a metallized film is used as a cover layer, a metal layer can be deposited over the thin film surface and the photoresist can be removed to reveal the exposed thin film underneath.

While technology is discussed with reference to photolithography, it is recognized that other methods of creating precisely located patterned layers on the thin film surface could be used. Unless explicitly stated, use of photolithography can be substituted by any of the known methods for generating a patterned layer of precise location. It will also be apparent from the description that follows that the method is not limited to silicon thin film crystallization and may be practiced for any thin film. For the purposes of discussion that follows, unless specifically noted, the methods may be used for any such material.

Irradiation of the film is carried out with a pulsed light source having the energy density to melt or partially melt the film of interest. The pulsed light source can be a divergent or flood light source that can cover a large surface and preferably the entire surface. Irradiation is typically a flood irradiation process, so that large areas of the substrate surface can be irradiated in a single pulse. It is possible that the entire film on a substrate, for example a glass panel, can be processed simultaneously. Multi-pulse operations therefore are used to provide an improved crystallographic property and are not required to be used in a scanned fashion to cover a large substrate area, for example, as used in laser-based recrystallization.

In one or more embodiments, the irradiation source is a pulsed excimer laser. High energy-per-pulse excimer lasers are presently being considered for ultra rapid thermal annealing (RTA) for creating shallow junctions. The high energy per pulse allows one to radiate an entire chip with one pulse.

In other embodiments, a diode laser can be used, which is capable of pulsed lasing at, for example, ˜800 nm. High power diode lasers can be power efficient and can have high divergence, making them suitable for high area coverage.

In other embodiments, a flash lamp can be used; it allows the entire wafer or even glass panel to be processed. The ideal light source depends on the particular application. Flash lamp is more taxing to the substrate and underlying structures (which could be electronic devices in 3D-IC), while providing cheaper processing, longer lateral growth, but maybe also more defective lateral growth and increased surface roughness. Surface roughness can be reduced with chemical mechanical polishing (CMP).

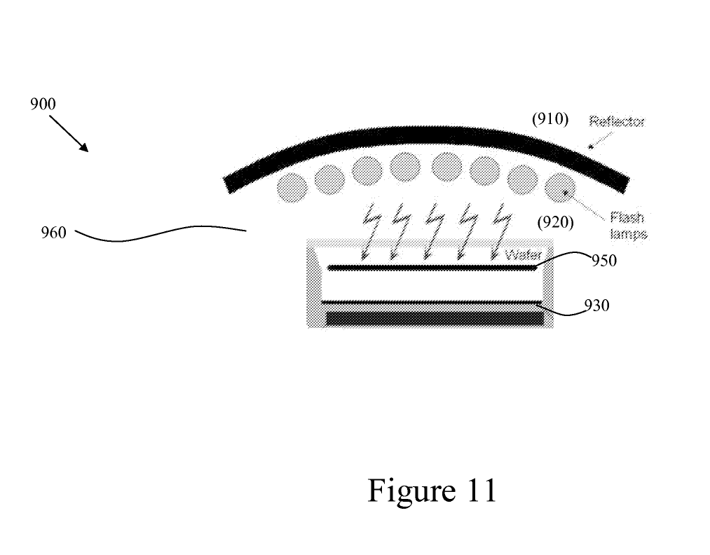

Flash laser annealing uses a flash lamp to produce white light over a wide wavelength range, e.g., 400-800 nm. The flash lamp is a gas-filled discharging lamp that produces intense, incoherent full-spectrum white light for very short durations. A flash lamp annealing apparatus uses white light energy for surface irradiation, in which the light is focused using, for example, an elliptical reflector to direct the light energy onto a substrate, such as is shown in FIG. 11. FIG. 11 is a simplified side view diagram representing a flash lamp reactor 900 with a reflecting device 910. The flash lamp reactor may include an array of flash lamps 920 located above a support 930, with a target area 950 situated between the two. The reflecting device 910 may be positioned above the flash lamps to reflect varying amount of radiation 960 from the flash lamps back towards different portions of a facing side of the target area. The target area may be adapted to receive a substrate (wafer).

The lamp power is supplied by a series of capacitors and inductors (not shown) that allow the formation of well defined flash pulses on a microsecond to millisecond scale. In a typical flash lamp, light energy densities in the range of up to 3-5 J/cm² (for a 50 μs discharge) or 50-60 J/cm² for a 1-20 ms discharge can be obtained. In exemplary embodiments, the light energy density can be about 2-150 J/cm². Flash lamp annealing allows fast heating of solid surfaces with a single light flash between some tens microseconds and some tens milliseconds, e.g., 10 μs-100 ms. Variables of the flash lamp that affect the quality of thin film crystallization include the energy intensity of the incident light, as well as the pulse duration and shape of the light (which results in a certain dwell time, i.e., a duration of melting).

In one or more embodiment, the capping layer can be used for precise location of melt-induced lateral growth using Controlled Super Lateral Growth (C-SLG). In the C-SLG method, the location and extent of melting induced by the incident light is controlled and limited to a specific region of the film using a photolithographically applied capping layer. The capping layer includes a pattern that exposes a precisely located region of the thin film to melting. When the molten region cools down and solidifies, crystal grains grow laterally in that region in a manner that is less random than the conventional polycrystalline films.

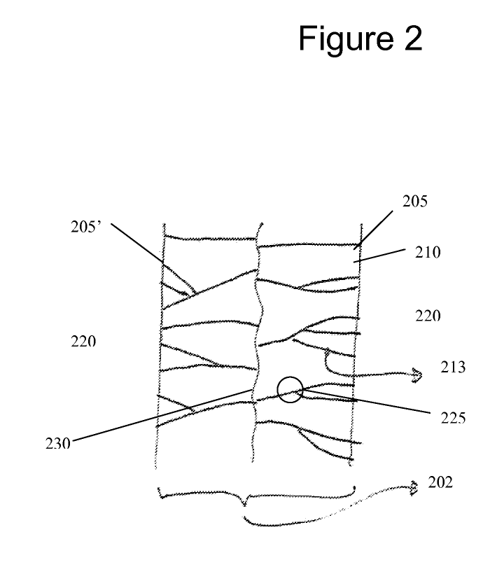

FIG. 2 is a top view schematic illustration of a portion of a film 200 which includes a region 202 that has been crystallized using C-SLG. During C-SLG, the treated region 202 is melted and solidification is initiated at the solidus-liquidus interface 205, 205′ between melted region 202 and unmelted regions 220, 220′. Crystalline grains 210 grow laterally, starting from boundaries 205 and 205′, towards the center of the treated region 202, meeting at centerline 230, which forms a long grain boundary perpendicular to the direction of solidification. Each section contains crystalline grains 210 separated by grain boundaries 213. As the grains grow laterally inward, occlusion defects, marked as 225, can form for example by intersecting with another grain boundary. The width of each section is defined by the lateral growth length (LGL) which is also the typical horizontal width of the largest grains in each section. The value of LGL is roughly half of the width of the treated region 202. LGL is also bound by a maximum value LGLₘₐₓ, which is the maximum length that a typical grain can grow before the lateral solidification is halted by random nucleation of solids in the supercooled liquid. LGLₘₐₓ depends on the characteristics of the film and the incident light, e.g., thickness and composition of the film and the melt temperature. Thus in a typical C-SLG method, the width of the treated region should not exceed twice LGLₘₐₓ.

The crystallization method enhances the quality of the treated film by increasing the average size of grains and decreasing the number of defects in the treated regions. Nevertheless these enhancements are still limited. For example, the treated regions can still include a relatively high density of occluded defects near crystallization boundaries. Further, the size of the grains in a C-SLG treated film is not uniform. Instead, the size of the occluded grains is often much smaller relative to the size of the persistent grains. Moreover, even for the persistent grains, the length is bound by the value of LGL, itself having a maximum value LGLₘₐₓ. Finally, due to the existence of occluded grains, the density of grain boundaries is not uniform. In C-SLG characterized by a single lateral growth step in the crystallization process, more that 50% of the grains are occluded or do not span the full length of the lateral growth.

In order to reduce the number of randomly located occluded grains, some embodiments utilize successive crystallization steps using lithographically positioned cap layers such that crystal grains that grow in each step overlap the grain boundaries formed in previous steps. With each iteration, the location of the treated region can be shifted such that the newly treated region partially overlaps with the previously treated region. The successive steps reduce the number of occluded grains and result in a more uniform grain structure that form crystallographic areas suitable for precision devices. The overlap, if chosen properly, can reduce the number of defects, specifically the number of occluded grain boundaries, and also can extend the grains created in the previous iteration. In one or more embodiments, more than 50% or more than 75% or more than 90% of the grains have a grain length that is commensurate with the lateral growth length, that is, the grains are not occluded.

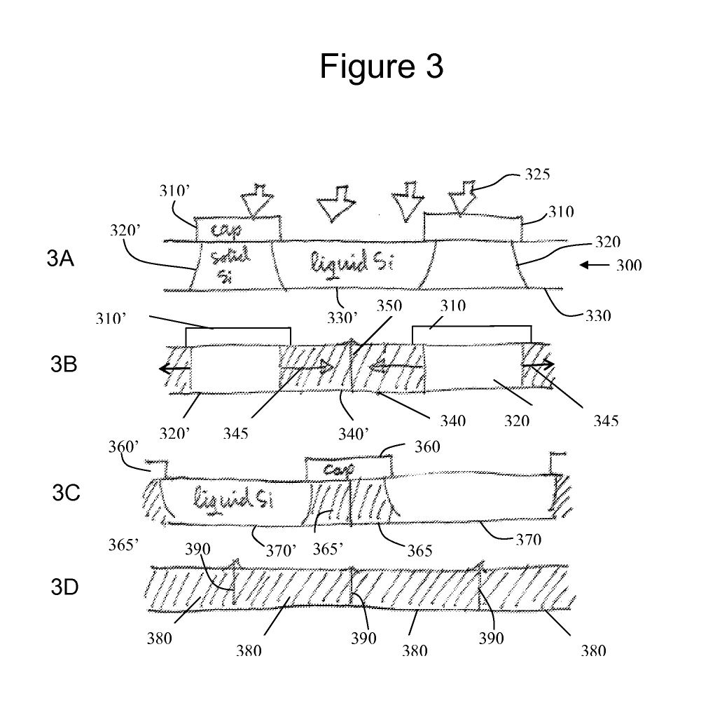

FIGS. 3A-3D depict cross sectional views of consecutive steps in a lithographically controlled crystallization process which is suitable for creating precision devices, according to one or more embodiments. The use of a lithographic cap layer that can cover large areas of the film, coupled with the use of flood or divergent light source, provides a high quality film in a few steps.

FIG. 3A shows the cross section of the lithographically processed film during the first step. A silicon layer 300 is covered with lithographically positioned cap layers 310, 310′. Cap layers 310, 310′ are position with a high degree of precision. For example, their location on the wafer is controlled to within 10-100 nm or about 10-50 nm. The capped silicon layer is then irradiated from above, for example, with a pulsed laser beam or pulsed flash lamp, as indicated by arrows 325. The energy density of the laser beam is chosen such that sections 320, 320′of silicon film 300 that are shielded from direct irradiation by cap layers 310, 310′ do not melt, while sections 330, 330′ of the silicon film 300 that receive radiation do melt.

The capping layer can be a continuous film with a plurality of openings. The cap layer can be made from a variety of materials, and can be reflective, absorptive or both. The cap layer can be made of conventional photoresist material. The cap layer can be made of conventional photoresist material followed by a baking step to convert the photoresist into carbon graphite. It can also be made of other materials that may be tolerant to the high energy density conditions of irradiation.

In some embodiments, the cap layer can be non-absorbing or opaque to the incident radiation. In other embodiments the cap layer can be reflective to the incident radiation. Absorptive materials tend to absorb the incident radiation and heat up. The heat can be transferred to the underlying film in a crystallization process. Reflective or opaque materials shield the underlying material from the incident radiation, so that the underlying material is cooler than the surrounding exposed areas. If the capping layer is reflective, it can be composed of any reflective material, for example, a metallic material, such as, e.g., aluminum. It may be desired to place a thin barrier layer such as, e.g., SiO₂ between the metallic cap layer and the film to prevent metal diffusion. In general, it should shift the melting threshold of the underlying film. Typically, as described by FIG. 3, this would be an upward shift, but of course, it could be a downward shift for example when using an antireflective coating when using monochromatic light (i.e., laser, not lamp).

FIG. 3B shows the cross section of the lithographically processed film during the second step, as lateral crystallization is initiated from the liquidus-solidus line generated by the irradiation process. With no radiation, melted sections 330 and 330′ cool down and crystallize laterally (as indicated by arrows 345), starting from their borders with solid sections 320, 320′ and forming crystallized sections 340, 340′ terminating at perpendicular grain boundary 350. Thus far, the process is similar to a single step C-SLG process in which a lithographic cap is used.

In yet another embodiment, the system can have one or more underlying absorber layers that can absorb the longer wavelength radiation from flash lamps or diode lasers. These absorber layers can be positioned between the thin film and the substrate or below the substrate. Because they preferentially absorb the longer wavelength radiation, the absorber layer will heat up first and can transfer the thermal energy from the radiation to the film to induce melting, while other regions in the film are heated by shorter wavelength light only and may remain solid. Because the flash lamps provide broad spectrum light, this arrangement provides the most efficient capture of the full energy spectrum of the flash lamp radiation and also can permit the capture of radiation that is transparent to the Si. These absorbing layers can be composed of any heat absorbing material, for example a metallic substance, for example, molybdenum. Thus, the above embodiment offers ways of accurately defining the location of regions of lateral growth using a non-patterned light source.

In a next step, the first cap layers are removed using methods known to those skilled in the art, e.g., oxygen plasma to remove carbon or wet chemical etching to remove metallic films.

FIG. 3C shows the cross section during the third step. In this step, the silicon layer 300 is covered with second lithographically positioned cap layers 360, 360′ which cover a central section 365, 365′ of each of the crystallized sections 340, 340′. The film is once again irradiated from above. The radiation melts sections 370, 370′ which are not covered by the cap layers 360, 360′. Non-crystallized sections 320, 320′ as well as those parts of the previously crystallized sections 340, 340′ which are not covered by the cap layers 360, 360′ are melted and laterally resolidified.

The resultant films have elongated laterally grown layers 380 having more than 50% or more that 75% or more than 90% of unoccluded grains having a length that is commensurate with the lateral growth length. Furthermore, because the capping layers and resultant laterally crystal growth are conducted with precision, i.e., placement of the capping layers within 10-50 nm of a known location, the long grain boundaries 390 are also known with precision. The accuracy of the placement of the long grain boundaries, i.e., the grain boundaries perpendicular to the crystal growth direction, can be known to within 10 nm to 800 nm, or 100 to 400 nm, or 100-200 nm. As is discussed in detail below, placement of the long grain boundaries with 100-200 nm accuracy permits the placement of devices at any desired location with a knowledge of the nature of the underlying grain structure.

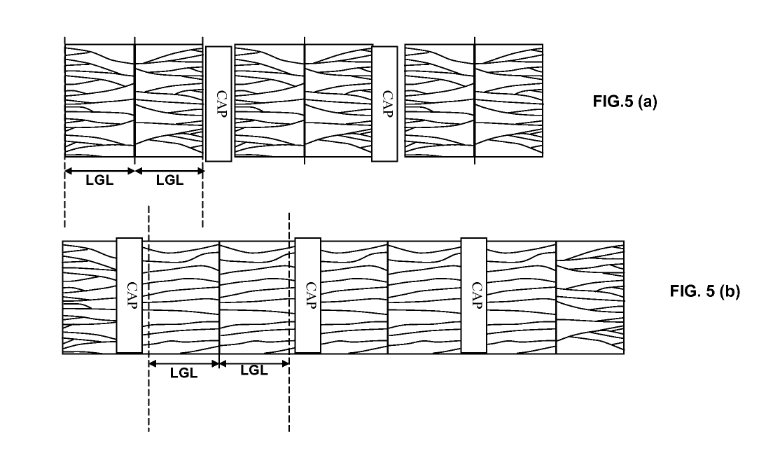

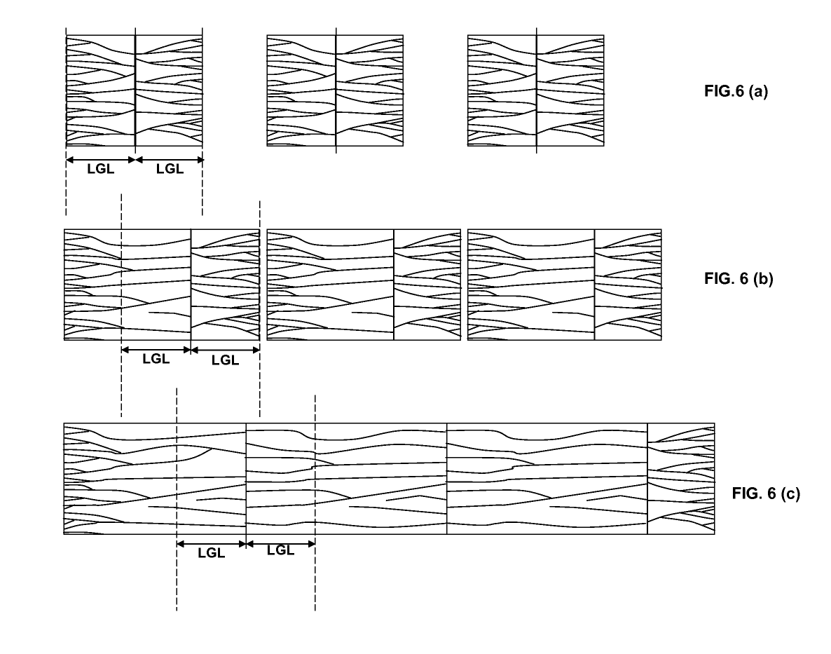

The lithographic mask can be used in any configuration to provide any type of crystallization growth or elongation generally known in the field. By way of example, the cap layers can provide plurality of elongated openings, such rectangles or stripes. A series of irradiations can be conducted, in which the cap layer is repositioned to overlap a portion of the previously irradiated film. The resulting films can provide regions of location-controlled crystalline grains comprising at least one pair of substantially parallel long grain boundaries and a plurality of elongated grains spanning adjacent long grain boundaries. A sequence of three irradiations using cap layers defining rectangular areas and resulting in adjacent columns of horizontally positioned elongated grains spanning vertical grain boundaries is shown in FIG. 5A-5B. In FIG. 5A, irradiation through a capping layer having exposed rectangular features provides three exposed areas that are subjected to melt and lateral growth. The capping layer can cover all, or a substantial portion, of the entire wafer. The first capping layer is removed and a second capping layer is deposited so that the exposed rectangular features partially overlap those of the first capping layer. The underlying film is irradiated, causing melting and lateral crystal growth, resulting in elongated grains running perpendicular to the long grain boundary. This method grows longer grains than otherwise possible with C-SLG, with a smoother surface. Even longer grain growth is possible if the initial exposed regions are spaced further apart and additional irradiation steps are added, as illustrated by the “short-scan directional” or a 3-shot process example set out in FIG. 6A-6C. Further detail of sequential lateral growth of crystals is found in U.S. Pat. No. 6,555,499, which is incorporated herein by reference. In each of these melt and lateral growth operations, the crystallization front terminates in a long grain boundary that runs perpendicular to the direction of grain growth. The location of the melted region is precisely defined by the capping layer and the crystallization based on the film and irradiation conditions, so that it is possible to predict the location of the long grain boundary to within about 100-200 nm. In such cases, the location of the long grain boundary can vary between about 5-10% of the lateral growth length.

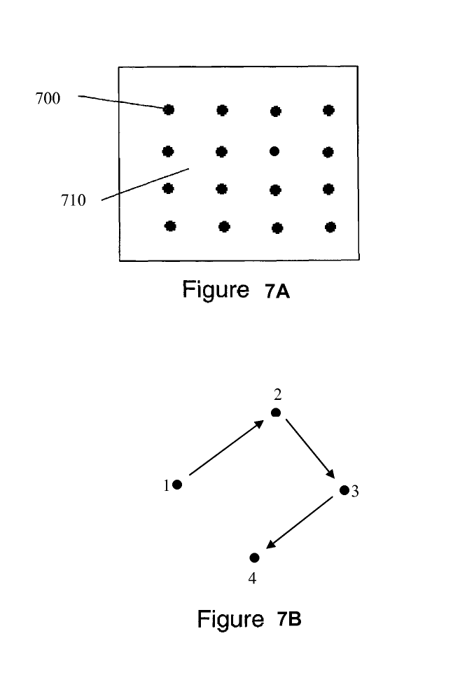

In other embodiments, the cap layer can be a small opaque region, or “dot,” and the surrounding region can be melted completely. FIG. 7A illustrates an exemplary cap layer in which regions or “dots” 700 are opaque and are precisely, e.g., lithographically, positioned over exposed film 710. Crystals grow laterally from the opaque center. Upon irradiation, all but the regions masked by the dots 700 melt and the solid islands serve as seeding sites for lateral crystal growth. The size and location of the dots are selected so that the laterally grown regions overlap between successive irradiations. By locating subsequent “dot” cap layers at distances within the characteristic lateral growth length of the crystals, the crystallized region can approach the quality of a single crystal. In one embodiment, the “dot” cap layers are sequentially located at the four corners of an imaginary square in which the sides are less than the characteristic lateral growth length of the crystals, as illustrated in FIG. 7B. Other irradiation patterns, using more or less dots are also contemplated. It is desirable to reduce the number of lithographic steps that need to be carried out and in may cases, three steps of patterning and irradiation can be sufficient.

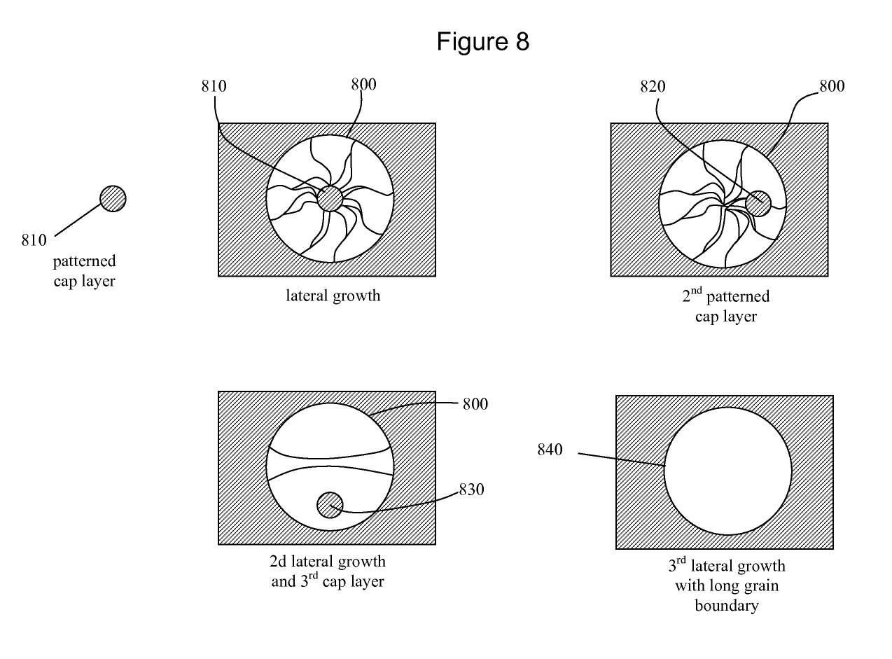

An irradiation pattern using three steps is illustrated in FIG. 8. In the dot irradiation process, an array of dots 810 such is shown in FIG. 8A are deposited lithographically on film 800 and irradiated. As shown in FIG. 8B for a single dot, the region under the dot provides a solid boundary, from which seed crystals can initiate the lateral growth of crystals. The islands grow radially away from the unmolten region (as opposed to the situation described above for rectangular regions, where growth is directional). If the separations distance between dots is greater than two times the lateral growth length, a crystalline structure is formed where crystals are separated by small grained polycrystalline silicon regions. If the separation distance is less then or equal to the lateral growth length so as to avoid nucleation, a crystalline structure where crystal islands abut one another forming a square grid is formed. If the islands grow in a square grid (because of the patterned layer consisting of a square array of dots), the long boundary approximates not a circle, but a square and it is therefore not perpendicular to the lateral growth. The first cap is then removed and a second cap 820 is deposited at a location spaced a distance from the first location, as shown in FIG. 8C. After irradiation, melting and lateral growth, the number of grain boundaries is reduced (the size of the crystal island may also be large if there is sufficient space between adjacent dots). A third and final dot 830 is deposited lithographically and irradiated. After three cap layer depositions and irradiations, a crystal island is formed having a long grain boundary 840 that encircles the central cap layer (which is subsequently removed). The island will have a substantially planar bottom interface and will have a substantially uniform thickness, wherein thickness variation in less than 50% or less than 25% for the interior region (away from the long grain boundaries, for example, by 10% or by 20% of the LGL). Protrusions that are formed at the long grain boundaries may show larger thickness variability, for example up to 100% or even 200%. Surface smoothness can be significantly enhanced using chemical mechanical polishing (CMP) resulting in further improvement of film thickness uniformity to for example a variation of less than 10% or less than 5% in the interior regions. The island, due to the single grain formation, will tend to have a random crystallographic surface orientation. The defectiveness of the island is found to depend on the surface crystallographic orientation, with special cases being {111} and {100} that have a low density of twin boundaries and an interior region substantially free of any planar defects, respectively. A method is described in US Publ. Appln. No. 2006/0102901 that is effective in producing a plurality of islands with the same surface orientation and typically more than 90% of the crystal islands have substantially the same crystallographic surface orientation, for example within 15° of a {100} surface orientation. Further detail of sequential lateral growth of crystals using a dot pattern is found in U.S. Pat. No. 7,311,778 and US Publ. Appln. No. 2006/0102901, which are incorporated herein by reference.

The long grain boundary for single grains is not determined with the same level of precision as with parallel long grain boundaries. As is described in copending US Publ. Appln. No. 2006/0102901, which is incorporated herein by reference, the resultant single crystal islands may be made up of different crystallographic grain orientations and each orientation will produce a crystal island having a different shape. Thus, for example, islands having primarily {100} surface orientation could produce faceted growth that results in islands that may be square in shape, while islands having predominantly {111 } surface orientation could produce faceted growth that may be hexagonal in shape. In such cases, the location of the long grain boundary can vary between about 10-20% of the lateral growth length.

In some applications which use precision devices, the precision device cannot tolerate the existence of any defects. Some other applications that can tolerate some defects, cannot tolerate a lack of uniformity in performance which can arise if the number or location of defects changes among different devices. On the other hand, some precision devices, e.g., microscopic devices such as 3D integrated circuits, may not tolerate the existence of defects at all, or they may not tolerate a variation in the number or location of those defects covered by the device. The lithographically located crystallized thin films can be used to precisely locate a device in the film relative to grain boundaries and other defects.

The number of defects (considered to include intergrain defects such as grain boundaries as well as intragrain defects such as twinning, stacking faults, and crystal point defects) covered by a device may depend on the size and location of the device. The performance of the smaller devices can be strongly influenced by the number of defects contained in the device. For smaller devices, the number of grain boundaries covered by each device varies by a relatively large percentage with even small variations in the position of the device with respect to the approximately periodic microstructure of the film.

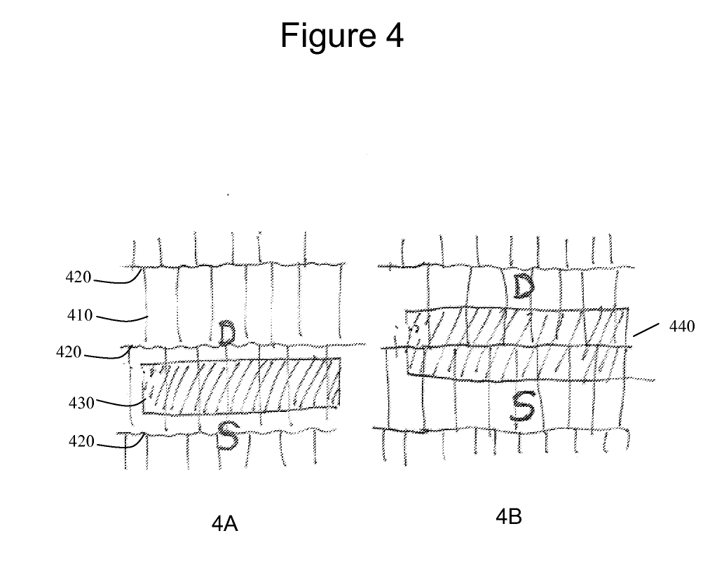

FIG. 4 is a plan view of a crystallized surface in which long grain boundaries 420 are precisely known using lithographic crystallization techniques. Spanning grain boundaries 410 are not as precisely known, since their location is determined in part by the recrystallization process. However, use of multiple irradiation method such as illustrated in FIGS. 3A-3D, FIGS. 5A-5B, FIGS. 6A-6C and FIG. 7 can improve, e.g., reduce, the number of grain boundaries, and defects such as inclusions, twinning and the like. Furthermore the negative impact such defects have on the device can be minimized if the device is design to promote electron mobility is the direction of the lateral grains and spanning grain boundaries 410. In FIG. 4A, the device 430 is a channel region of a TFT. The channel is placed in the region between two long grain boundaries 420 and electron flow between the source “S” and the drain “D” is parallel to spanning grain boundaries 410. In contrast, device 440 shown in FIG. 4B spans a horizontal grain boundary and will demonstrate reduced electron mobility. The microstructure can be obtained either through conventional SLS methods using projection masks or through the present lithographic technique. However, while with conventional SLS the devices are randomly placed with respect to the microstructure, the current method allows the devices to be placed accurately everywhere on the wafer. In one or more embodiments, the device may be placed entirely within a crystallized region 430, or spanning a long grain boundary such as device 440. A device can even be placed with one edge overlapping a grain boundary, for example, to reduce hot carrier degradation. The ability to place such devices reliably and accurately at the desired location arises from the lithographic crystallization that can accurately locate the long grain boundaries of the crystallized film.

Exemplary devices include transistors for 3D integrated circuits, TFT made from a patterned Si film, and SOI (silicon on insulator) MOSFET made from a continuous Si film on an insulator. Transistors (which includes bipolar transistors, field effect transistor, such as TFT and MOS) are contemplated. If the film is used to make TFTs, portions of the film are etched away and possibly most of the long grain boundaries. Most typically, there will be some long grain boundaries left, but in the case of the dot cap layer processing, the long grain boundary may not necessarily circumscribe the island anymore. For example, on two sides of the island, the long grain boundary will be etched away.

Larger devices, on average cover roughly equal numbers of defects from device to device and will not demonstrate significant variability in performance among devices. However, the placement of the device can nonetheless affect performance. Due to the larger size, the variation in the number of grain boundaries covered by the device, relative to the total number of those grain boundaries, is small. On the other hand, the location of those grain boundaries with respect to the device can vary based on the positioning of the device with respect to the grains. For example, a device can be positioned such that one horizontal grain boundary (using the orientation set out in FIG. 4) is located within the channel and very close to the device edge, which for example can be the location of the drain of the transistor. Such grain boundaries could affect the performance of the device much more than grain boundaries located in the middle of the device, away from the location of the drain or the source.

Other embodiments may employ the lithographic placement of elements other than cap layers that direct the melting and crystallization of the semiconductor film in a way that provides precise location of the crystalline regions. By way of example, elements that selectively withdraw heat from the irradiated silicon film, e.g., heat sinks, could be used to generate precisely located regions in the film that either fully melt (where heat sink is absent) or do not melt or only partially (where in contact with or in close proximity of the heat sink) so that grain growth can proceed and laterally extend from the partially melted region into fully melted region. A subsequent irradiation can be conducted that extends crystalline grain growth or improves the quality of existing grains by using a second lithographically placed element in the device.

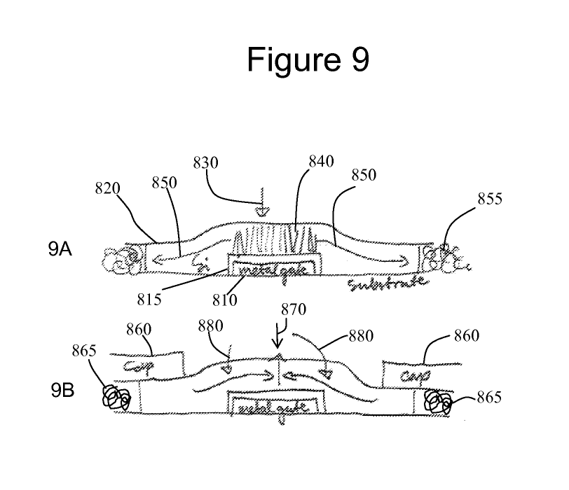

FIG. 9 is a cross-sectional illustration of an electronic device 800 including a metal gate 810 that illustrates this principle. The device includes a metal gate on a conventional substrate, e.g., silicon. The metal gate may be prepared of any conventional material and can be coated with a buffer or diffusion layer 815 to prevent interaction with subsequently deposited materials. A silicon layer 820 is deposited over the metal gate to a desired thickness. The substrate can then be irradiated with an energy density, pulse duration and irradiation intensity (indicated by arrow 830) to melt the silicon layer throughout its thickness every where except above the metal gate. The metal gate serves as a heat sink to withdraw heat from the silicon in direct contact with the metal gate, so that the adjacent silicon only partially melts 840. When the irradiation is withdrawn, the partially melted silicon provides seed crystals for the lateral growth of the silicon layer as indicated by arrows 850 in FIG. 9A. Lateral growth will continue until the silicon cools to point where nucleation 855 occurs. The remaining silicon region above the metal gate can be crystallized using a second lithographically placed cap layer 860, as indicated in FIG. 9B. The cap layer is positioned to cover at least the edges of the laterally grown crystals form the prior irradiation. The exposed region is then irradiated a second time at an energy density, pulse duration and irradiation intensity (as indicated by arrow 870) sufficient to melt the silicon layer throughout its thickness, even above the metal gate. This time, lateral growth is initiated at the cap layer edge and propagates toward the center as indicated by arrows 880 in FIG. 9B.

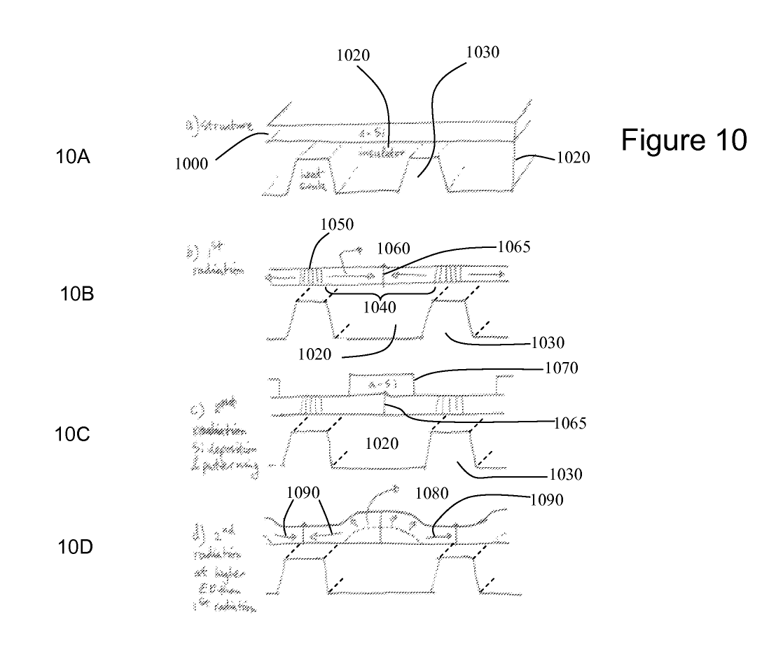

FIGS. 10A-10D illustrations another embodiment may employ the lithographic placement of elements other than cap layers that direct the melting and crystallization of the semiconductor film. As shown in FIG. 10A, an amorphous silicon layer 1000 is deposited on a lithographically structured substrate 1010 having insulating regions 1020 and heat sinks 1030. The amorphous silicon layer is then irradiated with flood irradiation with a light energy that is absorbed by the film. The film melts through its thickness at regions 1040 that overlay the insulating region and only partially melts at regions 1050 that overlay the heat sinks, as the heat sinks draw heat away from the film, as illustrated in FIG. 10B. When the irradiation is withdrawn, the partially melted silicon provides seed crystals for the lateral growth of the silicon layer as indicated by arrows 1060 in FIG. 10A. A long grain boundary 1065 is formed where the crystallization fronts meet. An amorphous silicon capping layer 1070 is then lithographically deposited on the silica layer at a location that overlays the long grain boundary 1065, while leaving partially melted regions 1050 exposed, as illustrated in FIG. 10C. The film is then subjected to a second irradiation that is at a higher energy density than the first irradiation so that the amorphous silica cap is melted through its thickness. However, the underlying silicon 1080 does not melt through, which serves as the seed crystal for lateral crystal growth.

Upon review of the description and embodiments of the present invention, those skilled in the art will understand that modifications and equivalent substitutions may be performed in carrying out the invention without departing from the essence of the invention. Thus, the invention is not meant to be limiting by the embodiments described explicitly above, and is limited only by the claims which follow.

What is claimed is:

1. An apparatus, comprising:
a semiconductor film comprising at least one region of laterally grown crystalline grains, said grains comprising at least one pair of substantially parallel long grain boundaries and a plurality of laterally grown grains spanning between adjacent long grain boundaries, and said grains having substantially uniform grain structure in which greater than about 50% of the grains have a length longer than the lateral growth length; and
a device located in said region at a location that is defined relative to the location of at least one long grain boundary of the crystalline grains.

2. The apparatus of claim 1, wherein the location of the long grain boundaries on the film are known with an accuracy of less than 10% of the lateral growth length.

3. The apparatus of claim 1, wherein the location of the long grain boundaries on the film are known with an accuracy of less than 5% of the lateral growth length.

4. The apparatus of claim 1, wherein the device is a transistor.

5. The apparatus of claim 4, wherein the transistor is a field effect transistor (FET) and is positioned within the region at a location where the channel of the FET does not contain a long grain boundary.

6. The apparatus of claim 4, wherein the FET is positioned within the region at a location where the source or the drain of the FET does not contain a long grain boundary.

7. The apparatus of claim 4, wherein the FET is positioned within a region at a location where the channel intersects a long grain boundary at a known location.

8. An apparatus, comprising:
a semiconductor film comprising a plurality of laterally grown crystalline islands, said islands comprising at least one long grain boundary, the long grain boundary circumscribing one of the islands at a distance from the island center of greater than the lateral growth length, and wherein the interior regions of the islands have substantially uniform film thickness
a device located in said region at a location that is defined relative to the location of at least one long grain boundary of the crystalline islands.

9. The apparatus of claim 8, wherein greater than 90% of the islands have the same surface crystallographic surface orientation.

10. The apparatus of claim 9, wherein the crystallographic surface orientation is a {100} plane.

11. The apparatus of claim 9, wherein the crystalline grain orientation comprises about 90% of the island surface area having a {100} surface orientation within about 15° of the {100} pole.

12. The apparatus of claim 9, wherein the crystallographic surface orientation is a {111} plane.

13. The apparatus of claim 9, wherein the crystalline grain orientation comprises about 90% of the island surface area having a {111 } surface orientation within about 15° of the {111} pole.

14. The apparatus of claim 8, wherein the location of the long grain boundaries on the film are known with an accuracy of less than 20% of the lateral growth length.

15. The apparatus of claim 8, wherein the location of the long grain boundaries on the film are known with an accuracy of less than 10% of the lateral growth length.

16. The apparatus of claim 8, wherein the device is a FET, comprising a channel source and drain.

17. The apparatus of claim 16, wherein the FET is positioned within the region at a location where the channel of the FET does not contain a long grain boundary.

18. A method of making an apparatus, comprising:
first irradiating a first region of a semiconductor film under a first set of conditions that induce controlled superlateral growth from a first boundary in the film, wherein the first boundary is lithographically defined;
second irradiating a second region of the film that only partially overlaps the first region under a second set of conditions that induce controlled superlateral growth from a second boundary in the film, wherein the second boundary is lithographically defined,
wherein said first and second irradiating provide a film comprising laterally grown crystalline grains having a length longer than the lateral growth length and at least one long grain boundary, wherein the location of the long grain boundary is known to within 20% of a lateral growth length; and
manufacturing an electronic device in the semiconductor film at a location that is defined relative to the location of the long grain boundary.

19. The method of claim 18, wherein the irradiation of the first region, the second region or both melts the semiconductor film through out its thickness.

20. The method of claim 18, wherein irradiation for at least one of the first and second irradiation is a flood irradiation.

21. The method of claim 18, wherein the lithographically defined boundary is provided by lithographically forming a cap layer over at least a portion of the film.

22. The method of claim 21, wherein the cap has a pattern that exposes the underlying semiconductor film to irradiation in lithographically defined locations.

23. The method of claim 18, wherein the lithographically defined boundary is provided by lower layer disposed below the film.

24. The method of claim 23, wherein the lower layer is a heat absorbing material and wherein, during irradiation using a wavelength that is absorbed by the semiconductor film, the temperature of the overlying semiconductor film at lithographically defined locations is less than the temperature of adjacent regions of the semiconductor film.

25. The method of claim 23, wherein the lower layer is a material that is a heat absorbing material and wherein, during irradiation using a wavelength that is transparent to the semiconductor film, the temperature of the overlying semiconductor film at lithographically defined locations is greater than the temperature of adjacent regions of the semiconductor film.

26. The method of claim 18, where the cap layer is comprised of a material that is opaque to the energy of irradiation.

27. The method of claim 18, wherein the cap layer is comprised of a material that is reflective to the energy of irradiation.

28. The method of claim 18, wherein the cap layer is a lithographically defined dot or array of dots.

29. The method of claim 28 wherein the irradiation comprises:
irradiating a first region surrounding a first lithographically defined dot cap layer to melt the first region while the area under the first dot remains at least partially solid, wherein the melted region laterally crystallized from the interface between the solid and the liquid;
removing the first dot cap layer;
lithographically depositing a second cap layer, wherein the second dot cap layer overlaps a laterally crystallized portion of the first irradiation; and
irradiating a second region surrounding the second lithographically deposited dot cap layer to melt the second region while the area under the second dot remains at least partially solid, wherein the melted region laterally crystallized from the interface between the solid and the liquid.

30. The method of claim 18, wherein the cap layer exposes elongated regions of underlying semiconductor film, wherein the exposed region defines a geometry having at least one dimension that is less than twice the characteristic lateral growth length of the semiconductor film.

31. The method of claim 30 wherein the irradiation step comprises:
irradiating at least a portion of the film to fully melt the exposed elongated regions of the underlying film, while the area under the first cap layer remains at least partially solid, wherein the melted region laterally crystallized from the interface the solid and the liquid;
removing the first cap layer;
lithographically depositing a second cap layer, wherein the second cap layer overlaps a laterally crystallized portion of the first irradiation; and
irradiating at least a portion of the film to fully melt the exposed elongated regions of the underlying film, while the area under the second cap layer remains at least partially solid, wherein the melted region laterally crystallized from the interface between the solid and the liquid.

32. The method of claim 18, wherein the location of the long grain boundary is directed by the location of the lithographically placed boundaries and the lateral growth length of the grains.

33. The method of claim 18 wherein the location of the long grain boundaries on the film are known to an accuracy of less than 10% of the lateral growth length.

34. The method of claim 18, wherein the location of the long grain boundaries on the film are known to an accuracy of less than 5% of the lateral growth length.

35. The method of claim 29, wherein the location of the long grain boundaries on the film are known to an accuracy of less than 20% of the lateral growth length.

36. The method of claim 18, wherein the device comprises a FET.

37. A method of processing a film, comprising:
providing a semiconductor film having a heat sink disposed below the film, said heat sink positioned using a lithographic method;
irradiating the film at an energy density sufficient to only partially melt a film region located above the heat sink and fully melt the film adjacent to the partially melted region, wherein the melted region laterally crystallized from the interface of the partially melted region and the liquid;
positioning a cap layer over film in a pattern that exposes a portion of the laterally crystallized film; and
irradiating with film at an energy density sufficient to fully melt the exposed film throughout its thickness, while the area under the cap layer remains at least partially solid, wherein the melted region laterally crystallizes from the interface of the solid and the liquid.

38. A method of processing a film, comprising:
providing a semiconductor film having a first cap layer disposed above the film having a pattern that exposes a portion of the film, said cap layer positioned using a lithographic method;
irradiating the film at a first energy density sufficient to fully melt the exposed portion of the film throughout its thickness, while the area under the first cap layer remains at least partially solid wherein the melted region laterally crystallized from the interface of the partially melted region and the liquid;
positioning a second cap layer over film in a pattern that exposes a portion of the laterally crystallized film; and
irradiating with film at a second energy density sufficient to fully melt the exposed portion of the film throughout its thickness, while the area under the second cap layer remains at least partially solid wherein the melted region laterally crystallized from the interface of the partially melted region and the liquid.
